(19) United States
(12) Patent Application Publication
(10) Pub. No.: US 2026/0338842 A1
(43) Pub. Date: Oct. 29, 2026

(54) INFORMATION PROCESSING METHOD, INFORMATION PROCESSING DEVICE, AND RECORDING MEDIUM

(71) Applicant: Panasonic Intellectual Property Management Co., Ltd., Osaka (JP)

(72) Inventors: Kotaro SAKATA, Osaka (JP); Tetsuji FUCHIKAMI, Osaka (JP)

(21) Appl. No.: 19/700,689

(22) Filed: Jun. 8, 2026

Related U.S. Application Data
(63) Continuation of application No. PCT/JP2024/043975, filed on Dec. 12, 2024.

(30) Foreign Application Priority Data
Dec. 28, 2023 (JP) 2023-223093

(51) Int. Cl. G01R 21/133

(52) U.S. Cl. CPC G01R 21/1333

(57) ABSTRACT

An information processing method includes: obtaining, for each of a plurality of energy management systems, facility data of a facility managed in the energy management system; extracting an energy management system that is associated with facility data that is similar to facility data associated with one energy management system, and grouping together the energy management system extracted and the one energy management system; obtaining energy-supply-and-demand-amount data; and evaluating validity of energy-saving performance of the one energy management system by comparing the energy-supply-and-demand-amount data of each of the energy management systems grouped together, and outputting an evaluation result.

### CROSS REFERENCE TO RELATED APPLICATIONS

This is a continuation application of PCT International Application No. PCT/JP2024/043975 filed on Dec. 12, 2024, designating the United States of America, which is based on and claims priority of Japanese Patent Application No. 2023-223093 filed on Dec. 28, 2023. The entire disclosures of the above-identified applications, including the specifications, drawings and claims are incorporated herein by reference in their entirety.

### FIELD

The present disclosure relates to an information processing method, an information processing device, and a recording medium.

### BACKGROUND

There are energy management systems, such as microgrids that are provided for practical use. For example, Patent Literature (PTL) 1 discloses an energy management system for which the utilization efficiency of renewable energy, in terms of amount of power consumption in a microgrid, can be easily improved.

### CITATION LIST

### Patent Literature

PTL 1: Japanese Unexamined Patent Application Publication No. 2021-193861

### SUMMARY

### Technical Problem

However, there is a need related to the evaluation of such energy management systems. In view of this, the present disclosure provides an information processing method and the like for evaluating validity of an energy management system.

### Solution to Problem

An information processing method according to one aspect of the present disclosure is an information processing method for evaluating validity of one energy management system included in a plurality of energy management systems, the information processing method being executed by a computer, the information processing method including: obtaining, for each of the plurality of energy management systems, facility data of a facility managed in the energy management system; extracting an energy management system, from among the plurality of energy management systems, that is associated with facility data that is similar to facility data associated with the one energy management system, and grouping together the energy management system extracted and the one energy management system; obtaining, for each of the facilities managed in the energy management systems grouped together, energy-supply-and-demand-amount data; and evaluating validity of energy-saving performance of the one energy management system by comparing the energy-supply-and-demand-amount data of each of the energy management systems grouped together, and outputting an evaluation result.

Furthermore, an information processing device according to one aspect of the present disclosure is an information processing device that evaluates validity of one energy management system included in a plurality of energy management systems, the information processing device including: a facility data obtainer that obtains, for each of the plurality of energy management systems, facility data of a facility managed in the energy management system; a real-world cluster generator that extracts an energy management system, from among the plurality of energy management systems, that is associated with facility data that is similar to facility data associated with the one energy management system, and groups together the energy management system extracted and the one energy management system; an energy-supply-and-demand-amount data obtainer that obtains, for each of the facilities managed in the energy management systems grouped together, energy-supply-and-demand-amount data; and a validity evaluator that evaluates validity of energy-saving performance of the one energy management system by comparing the energy-supply-and-demand-amount data of each of the energy management systems grouped together, and outputs an evaluation result.

Furthermore, one aspect of the present disclosure can be implemented as a non-transitory computer-readable recording medium having recorded thereon a program for causing a computer to execute the above-mentioned information processing method.

It should be noted that these generic and specific aspects may be implemented as a system, a device, a method, an integrated circuit, a computer program, or a non-transitory computer-readable recording medium, such as a CD-ROM, or may be implemented as any combination of a system, a device, a method, an integrated circuit, a computer program, and a recording medium.

### Advantageous Effects

The present disclosure makes it possible to evaluate validity of an energy management system.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating a functional configuration of an information processing device according to an embodiment.

FIG. 2 is a flowchart illustrating operation of the information processing device according to the embodiment.

### DESCRIPTION OF EMBODIMENT

### Underlying Knowledge Forming Basis of the Present Disclosure

In recent years, due to changing attitudes toward energy-supply-and-demand, there is a growing need to implement energy-saving and cost-saving measures. In light of this background, energy management systems (EMS) that can manage energy supply and demand in a consolidated manner, on a basis of individual management units, are becoming more prevalent. On the other hand, even when energy-saving and cost-saving measures are already being implemented by such an energy management system, there are cases where further energy-saving and cost-saving measures can be achieved under similar conditions. In other words, there are cases where an energy management system may convey the impression that all possible energy-saving and cost-saving measures have already been exhausted, even when there is still a potential to implement further energy-saving and cost-saving measures. Accordingly, there is a need related to the evaluation of validity of such energy management systems (from an energy-saving and cost-saving standpoint, for example).

In view of this, we examine the concept of structural health monitoring. In general terms, this concept is known as a technique for estimating the progression of damage and deterioration of a structure that is predicted based on stress applied to the structure, and the technique involves actually measuring the stress applied to the structure, by means such as attaching sensors to various locations of the structure in order to evaluate durability and safety of the structure. In other words, in structural health monitoring, durability and safety of a structure are evaluated by estimating how such factors will progress over time, when the structure continues to be subjected to the same conditions.

Even for an energy management system, it can be presumed that equivalent energy-saving and cost-saving measures can be consistently implemented as long as the same conditions are maintained. Conversely, in a case in which equivalent energy-saving and cost-saving measures are not being implemented even though the same conditions are being maintained, it can be evaluated that valid energy-saving and cost-saving measures are not being implemented in the energy management system.

The present disclosure describes an information processing method for evaluating energy-saving and cost-saving measures implemented in individual energy management systems, among a plurality of energy management systems, in which those energy management systems that are being subjected to the same conditions are treated as a group, and evaluated based on differences in terms of energy-saving and cost-saving measures between the energy management systems of the same group.

A more specific outline of the present disclosure is described hereinafter.

An information processing method according to a first aspect of the present disclosure is an information processing method for evaluating validity of one energy management system included in a plurality of energy management systems, the information processing method being executed by a computer, the information processing method including: obtaining, for each of the plurality of energy management systems, facility data of a facility managed in the energy management system; extracting an energy management system, from among the plurality of energy management systems, that is associated with facility data that is similar to facility data associated with the one energy management system, and grouping together the energy management system extracted and the one energy management system; obtaining, for each of the facilities managed in the energy management systems grouped together, energy-supply-and-demand-amount data; and evaluating validity of energy-saving performance of the one energy management system by comparing the energy-supply-and-demand-amount data of each of the energy management systems grouped together, and outputting an evaluation result.

When evaluating the validity of the energy-saving performance of the one energy management system, such an information processing method can be used to evaluate the validity of the energy-saving performance by treating energy management systems having similar facility data as a single group, and comparing the energy-supply-and-demand-amount data of the energy management systems within the group. In a case in which such facility data is similar to each other, there is a tendency for energy-supply-and-demand-amount data to also be similar to each other among the energy management systems being compared. In other words, validity of energy-saving performance of other energy management systems within the group can be evaluated by examining whether there is a tendency for energy-supply-and-demand-amount data of the other energy management systems to also be similar to the energy-supply-and-demand-amount data of the one energy management system. Accordingly, this makes it possible to evaluate validity of an energy management system from the standpoint of tendencies in similarity between energy-supply-and-demand-amount data.

Furthermore, an information processing method according to a second aspect is the information processing method according to the first aspect, in which for each of the plurality of energy management systems, the facility data associated with the energy management system includes at least one of (i) a total-floor area of the facility, (ii) a device configuration of electrical devices provided in the facility, or (iii) a device attribute of the electrical devices provided in the facility.

Accordingly, energy management systems with similar facility data can be treated as a single group by using facility data that includes at least one of total-floor areas of facilities being managed in the energy management systems, device configurations of electrical devices provided in the facilities, and device attributes of the electrical devices provided in the facilities.

Furthermore, an information processing method according to a third aspect is the information processing method according to the first aspect or the second aspect, in which each of the plurality of energy management systems is (i) a home energy management system (HEMS) that manages energy supply and demand on a basis of a single-household unit, (ii) a building energy management system (BEMS) that manages energy supply and demand on a basis of a business-site unit, or (iii) a factory energy management system (FEMS) that manages energy supply and demand on a basis of a factory unit.

Accordingly, validity of an energy management system can be evaluated for an HEMS that manages energy supply and demand on a basis of a single-household unit, a BEMS that manages energy supply and demand on a basis of a facility unit, such as a business site or the like, or an FEMS that manages energy supply and demand on a basis of a factory unit.

Furthermore, an information processing method according to a fourth aspect is the information processing method according to the first aspect or the second aspect, in which each of the plurality of energy management systems is a microgrid.

Accordingly, validity of an energy management system can be evaluated for a microgrid.

Furthermore, an information processing method according to a fifth aspect is the information processing method according to the first aspect or the second aspect, in which each of the plurality of energy management systems is a community energy management system (CEMS) that manages energy supply and demand on a basis of a community unit that includes a plurality of households.

Accordingly, validity of an energy management system can be evaluated for a CEMS that manages energy supply and demand on a basis of a community unit including a plurality of households.

Furthermore, an information processing method according to a sixth aspect is the information processing method according to the first aspect or the second aspect, in which each of the plurality of energy management systems is a virtual power plant (VPP) that manages energy supply and demand that includes selling of electricity via a power-transmission network on a basis of a predetermined unit.

Accordingly, validity of an energy management system can be evaluated for a VPP that manages energy supply and demand that includes selling of electricity via a power-transmission network on a basis of a predetermined unit.

Furthermore, an information processing method according to a seventh aspect is the information processing method according to the sixth aspect, further including: obtaining energy-price data for each of the facilities managed in the energy management systems grouped together, in which the energy-supply-and-demand-amount data of each of the facilities managed in the energy management systems grouped together includes an electricity-sales amount and an electricity-purchasing amount of the facility managed, and in the outputting, validity of economic efficiency of the one energy management system is evaluated by further using (i) an electricity-sales amount and an electricity-purchasing amount of a facility managed in the one energy management system and (ii) the energy-price data obtained, and an evaluation result is output.

Accordingly, the validity of the economic efficiency of the one energy management system can be evaluated based on the electricity-sales amount and the electricity-purchasing amount, which are included as the energy-supply-and-demand-amount data.

Furthermore, an information processing method according to an eighth aspect is the information processing method according to any one of the first to seventh aspects, further including: obtaining, for each of the plurality of energy management systems, weather data that is associated with the facility managed in the energy management system, in which in the outputting, the validity of the energy-saving performance of the one energy management system is evaluated by comparing, from among the energy-supply-and-demand-amount data of each of the energy management systems grouped together, energy-supply-and-demand-amount data of energy management systems having weather data similar to each other, and an evaluation result is output.

Accordingly, the validity of the energy-saving performance of the one energy management system can be evaluated by comparing, from among the energy-supply-and-demand-amount data of each of the energy management systems grouped together, energy-supply-and-demand-amount data of those energy management systems having weather data similar to each other, or in other words, comparing only those energy management systems having similar weather data.

Furthermore, an information processing device according to a ninth aspect is an information processing device that evaluates validity of one energy management system included in a plurality of energy management systems, the information processing device including: a facility data obtainer that obtains, for each of the plurality of energy management systems, facility data of a facility managed in the energy management system; a real-world cluster generator that extracts an energy management system, from among the plurality of energy management systems, that is associated with facility data that is similar to facility data associated with the one energy management system, and groups together the energy management system extracted and the one energy management system; an energy-supply-and-demand-amount data obtainer that obtains, for each of the facilities managed in the energy management systems grouped together, energy-supply-and-demand-amount data; and a validity evaluator that evaluates validity of energy-saving performance of the one energy management system by comparing the energy-supply-and-demand-amount data of each of the energy management systems grouped together, and outputs an evaluation result.

Accordingly, the same advantageous effects as the above-mentioned information processing method are achieved.

Furthermore, a recording medium according to a tenth aspect is a non-transitory computer-readable recording medium having recorded thereon a program for causing the computer to execute the information processing method according to any one of the first to sixth aspects.

Accordingly, by using the computer, the same advantageous effects as the above-mentioned information processing method are achieved.

Furthermore, these general or specific aspects may be implemented as a system, a device, a method, an integrated circuit, a computer program, or a non-transitory computer-readable recording medium, such as a CD-ROM, or may be implemented as any combination of a system, a device, a method, an integrated circuit, a computer program, and a recording medium.

Hereinafter, exemplary embodiments will be specifically described with reference to the drawings. It should be noted that the embodiments described below merely illustrate generic or specific examples of the present disclosure. The numerical values, shapes, materials, elements, the arrangement and connection states of the elements, steps, the order of the steps, etc., described in the following embodiments are mere examples, and are therefore not intended to limit the present disclosure. Furthermore, among elements in the following embodiments, those not appearing in any of the independent claims will be described as optional elements. It should be noted that the respective figures are schematic diagrams and are not necessarily precise illustrations. Furthermore, in the respective figures, elements that are substantially the same are given the same reference signs, and redundant descriptions may be omitted or simplified.

### Embodiment

### [Configuration]

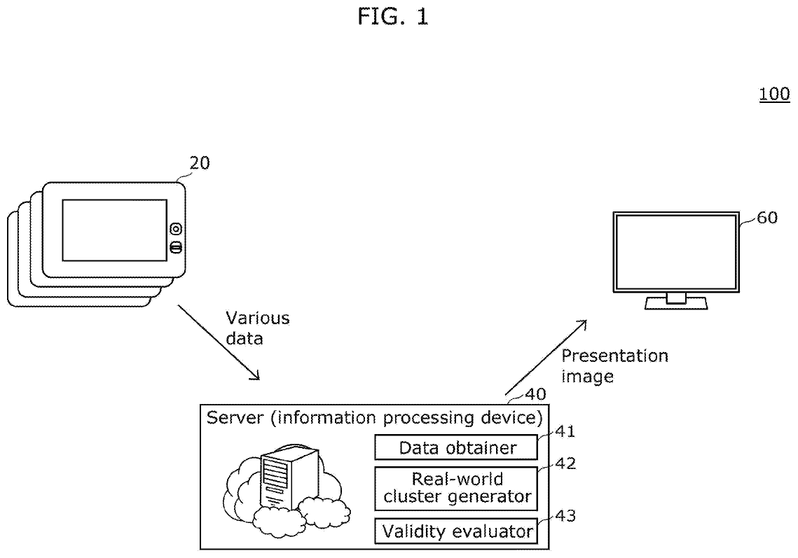

First, a configuration of an information processing system according to an embodiment will be described. FIG. 1 is a block diagram illustrating a functional configuration of information processing system 100 according to the embodiment. As illustrated in FIG. 1, information processing system 100 includes energy management systems 20 (only control terminals are illustrated here), server 40, and display device 60. Server 40, energy management systems 20, and display device 60 are communicably connected via a network, such as the Internet or the like. Each of the control terminals corresponds to a terminal that is capable of managing one energy management system. In other words, FIG. 1 illustrates that information processing system 100 includes a plurality of energy management systems 20. Furthermore, server 40 is communicably connected in a manner similar to a weather database not illustrated in the drawings.

Energy management system 20 is a group of devices that, in a consolidated manner, manages energy supply and demand for a facility that is a management target, and energy management system 20 is implemented by a control terminal, as illustrated in FIG. 1, and sensors or the like. Energy management system 20 can manage an energy balance of power consumption from the standpoint of energy-saving measures that are implemented through the purchasing of electrical power from an electrical grid (electricity purchasing) and the selling of electrical power generated at the facility to the electrical grid (electricity selling). In other words, for the energy management system, it can be evaluated that energy-saving measures are being implemented when an electricity-purchasing amount decreases, and it can be evaluated that energy-saving measures are not being implemented when the electricity-purchasing amount increases.

Alternatively, even when the electricity-purchasing amount does not decrease, if the electricity-sales amount increases, it can be evaluated that energy-saving measures are being implemented from an overall perspective. However, since such an evaluation is based on comparisons with past performance of the same energy management system, there are cases where even further energy-saving measures can actually be implemented. In other words, there are cases in which energy-saving performance of an energy management system can be improved upon.

It should be noted that the selling of generated electrical power to an electrical grid (electricity selling) can be achieved by a virtual power plant (VPP) that is designed to facilitate the selling of electricity via a power-transmission network. In the embodiment, an example will be described of a case in which a VPP is used as an energy management system. Alternatively, depending on the scale of the energy management system and the unit of the management target or the like, the energy management system may be a home energy management system (HEMS) that manages energy supply and demand on a basis of a single-household unit, a mansion energy management system (MEMS) that manages energy supply and demand on a basis of a plurality of households units in one building, a building energy management system (BEMS) that manages energy supply and demand on a basis of a facility unit, such as a business site or the like, or a factory energy management system (FEMS) that manages energy supply and demand on a basis of a factory unit. Furthermore, the energy management system may be a microgrid, and may be a community energy management system (CEMS) that manages energy supply and demand on a basis of a community unit that includes a plurality of households.

In a case in which the energy management system is a VPP, in addition to evaluation performed from the standpoint of energy selling and purchasing amounts, the energy management system can also be evaluated from the standpoint of cost fluctuations resulting from the selling and purchasing of energy, or in other words, a perspective focused on cost-saving measures rather than energy-saving measures. In other words, in this case, economic efficiency of the energy management system can be evaluated.

Server 40 is realized as a cloud server or an edge server in which functions of an information processing device are implemented, and is a device that processes information received as input, and outputs some other information. Server 40 includes a processor and a memory, and by executing a predetermined program stored in the memory, server 40 functions as an information processing device, by evaluating validity of energy-saving performance of energy management system 20 and outputting an evaluation result. Server 40 includes data obtainer 41, real-world cluster generator 42, and validity evaluator 43.

Data obtainer 41 includes a function to serve as a weather data obtainer that obtains weather data associated with each of the plurality of energy management systems 20, a function to serve as an energy-supply-and-demand-amount data obtainer that obtains energy-supply-and-demand-amount data of each of the plurality of energy management systems 20, a function to serve as a facility data obtainer that obtains facility data of each of the plurality of energy management systems 20, and a function to serve as an energy-price data obtainer that obtains energy-price data of each of the plurality of energy management systems 20. In the following description, although it will be described that data obtainer 41 obtains weather data, energy-supply-and-demand-amount data, facility data, and energy-price data associated with all of the plurality of energy management systems 20, once the energy management systems have been grouped together, data obtainer 41 need only obtain weather data, energy-supply-and-demand-amount data, and energy-price data exclusively for those energy management systems 20 in the group that is a target to be evaluated.

In data obtainer 41, information on the plurality of energy management systems 20 that are targets is registered. Specifically, facility data of each of the plurality of energy management systems 20 that have already been registered are stored in storage (not illustrated in the drawings) accessible by data obtainer 41. Furthermore, by accessing the storage, data obtainer 41 reads and obtains the facility data of each of the plurality of energy management systems 20 that have already been registered.

The facility data is data on a corresponding one of facilities being managed in energy management systems 20. The facility data includes, for example, at least one of a total-floor area of the facility, a device configuration of electrical devices provided in the facility, and a device attribute of the electrical devices provided in the facility, as well as information on the location of the facility. Since the electrical devices being managed by the corresponding energy management system and the scale of output and the like of the electrical devices can be estimated based on the total-floor area, it is possible to perform grouping, as described later, that is based exclusively on total-floor area. In a case in which more accurate grouping is desired, the facility data may include a device configuration and a device attribute of the electrical devices. A device configuration of electrical devices is information indicating how many of what kind of electrical devices are provided at a facility. Furthermore, a device attribute of electrical devices is information indicating the aggregate total of rated power of electrical devices provided at a facility. In addition to the scale estimated based on the total-floor area, by further including a device configuration and a device attribute of specific electrical devices, it can be more accurately determined in the grouping whether a given energy management systems should be included in the same group.

Weather data can be obtained, by data obtainer 41 querying a weather database based on information on locations of the facilities, as data related to weather conditions at the locations of the facilities, each of which is managed by a corresponding energy management system 20. There are cases where weather conditions can influence operating efficiency and the like of electrical devices located at a facility. For this reason, weather data is used for comparing energy management systems 20 having similar weather conditions.

Energy-supply-and-demand-amount data is obtained from a corresponding energy management system 20, and includes an electricity-sales amount and an electricity-purchasing amount for a corresponding one of the facilities. More specifically, the energy-supply-and-demand-amount data includes instantaneous values of the electricity-sales amount and the electricity-purchasing amount of the corresponding energy management system 20. The electricity-sales amount and the electricity-purchasing amount are continuously obtained and accumulated as data that changes over time.

Energy-price data is information obtained from a management server or the like maintained by an energy supplying company, and the information indicates a unit sales price for each unit of an electricity-sales amount and a unit purchasing price for each unit of an electricity-purchasing amount. Since energy-price data varies from moment to moment, energy-price data is obtained as information that changes over time.

From among the plurality of energy management systems 20, real-world cluster generator 42 generates groups of energy management systems 20 having similar facility data (also referred to as real-world clusters). As a result, one energy management system 20, which is a target to be evaluated, is included in a group that contains other energy management systems 20 having similar facility data. Accordingly, it becomes possible to compare those energy management systems 20 being subjected to similar conditions by simply comparing energy-saving performance and economic efficiency within the group.

In the generating of the group, it is determined that facility data is similar to each other when there is an 80 percent or more match for all parameters, among one or more parameters, such as physical quantities and the like included in the facility data. Furthermore, when there is an 80 percent or more match for 50 percent or more of parameters, among the one or more parameters, it is determined that the facility data is similar to each other. Furthermore, when there is a 50 percent or more match for 80 percent or more of parameters, among the one or more parameters, it is determined that the facility data is similar to each other.

It should be noted that the conditions for determining similarity for the above-mentioned facility data are merely an example, and may be adjusted in an appropriate manner in accordance with how many energy management systems 20 are to be included in a group.

Validity evaluator 43 extracts those energy management systems 20, from among energy management systems 20 in the group, that have weather data that is similar to weather data of the one energy management system 20 that is the target to be evaluated. In regards to determining similarity of weather data, it is determined that weather data is similar to each other when there is an 80 percent or more match for all parameters, among one or more parameters, such as physical quantities and the like included in the weather data. Furthermore, when there is an 80 percent or more match for 50 percent or more of parameters, among the one or more parameters, it is determined that the weather data is similar to each other. Furthermore, when there is a 50 percent or more match for 80 percent or more of parameters, among the one or more parameters, it is determined that the weather data is similar to each other.

It should be noted that the conditions for determining similarity for the above-mentioned weather data are merely an example, and may be adjusted in an appropriate manner in accordance with how many energy management systems 20 are to be extracted.

Next, validity evaluator 43 compares the energy-supply-and-demand-amount data obtained that are associated with the energy management systems 20 extracted. For example, for each of the energy management systems 20 extracted, an average of the energy-supply-and-demand-amount data is calculated. Using the average of the energy-supply-and-demand-amount data as a reference, a score on a five-level scale including the numbers 1, 2, 3, 4, and 5, or the like, is assigned to the energy management system 20 to indicate whether the energy management system 20 is (1) an energy management system 20 having energy-supply-and-demand-amount data significantly higher than the reference, (2) an energy management system 20 having energy-supply-and-demand-amount data somewhat higher than the reference, (3) an energy management system 20 having energy-supply-and-demand-amount data equivalent to the reference, (4) an energy management system 20 having energy-supply-and-demand-amount data somewhat lower than the reference, or (5) an energy management system 20 having energy-supply-and-demand-amount data significantly lower than the reference. Here, the higher the value of the score is, the more satisfactory the result. Next, as an evaluation result, information that indicates the scores assigned is output. In other words, validity evaluator 43 evaluates validity of the one energy management system 20, which is the target to be evaluated, from the standpoint of energy-saving performance. In some cases, the validity of the one energy management system 20 may be interpreted as the overall health of the one energy management system 20.

Furthermore, validity evaluator 43 also evaluates validity of the one energy management system 20 based on energy-price data. It should be noted that evaluation of the validity of the one energy management system 20 based on the energy-price data is not essential. First, calculations are performed on the energy-supply-and-demand-amount data obtained that are associated with the energy management systems 20 extracted to identify cost fluctuations (cost balance) with respect to electricity-sales amounts and electricity-purchasing amounts by using the energy-price data.

For example, validity evaluator 43 multiplies an electricity-sales amount by a unit sales price and subtracts the product of an electricity-purchasing amount and a unit purchasing price. Accordingly, the cost of energy consumed at a facility being managed in an energy management system 20 over a given period of time is calculated. Validity evaluator 43 compares the costs calculated with each other. For example, for each of the energy management systems 20 extracted, an average cost is calculated. Using the average cost as a reference, a score on a five-level scale including the numbers 1, 2, 3, 4, and 5, or the like, is assigned to the energy management system 20 to indicate whether the energy management system 20 is (1) an energy management system 20 having a cost significantly higher than the reference, (2) an energy management system 20 having a cost somewhat higher than the reference, (3) an energy management system 20 having a cost equivalent to the reference, (4) an energy management system 20 having a cost somewhat lower than the reference, or (5) an energy management system 20 having a cost significantly lower than the reference. Here, the higher the value of the score is, the more satisfactory the result. Next, as an evaluation result, information that indicates the scores assigned is output. In other words, validity evaluator 43 evaluates validity of the one energy management system 20, which is the target to be evaluated, from the standpoint of economic efficiency.

Furthermore, validity evaluator 43 displays an image pertaining to the evaluation result (list of scores assigned to the energy management systems 20) by outputting the image to display device 60 as a presentation image, and presents the image to an administrator or the like of the energy management systems 20, for example.

Display device 60 is a display device, such as a smartphone, a tablet device, a smartwatch, a television, a projector, or the like that includes a display, and is provided at a location in the surroundings of the administrator or the like, at which the image pertaining to the evaluation result is to be presented. It should be noted that a display in a projector refers to a projection plane, and it is understood that the terms projection device and projection plane are included in the terms used for such projectors. Furthermore, display device 60 may be smart glasses in which a display is provided in front of the eyes of an administrator or the like by the administrator or the like wearing the smart glasses. Display device 60 presents the presentation image to the administrator or the like by displaying the presentation image output from server 40 on the display. Based on an evaluation result that is obtained through proper evaluation and is presented in the above-mentioned manner, the administrator can consider whether maintenance or the like is required for an energy management system 20 that is anomalous.

### [Operation]

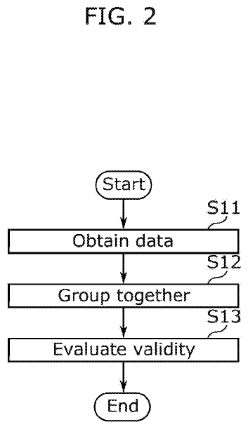

Next, operation of the above-mentioned information processing system 100 will be described with reference to FIG. 2, with a focus placed on operation of server 40. FIG. 2 is a flowchart illustrating operation of the information processing device according to the embodiment.

As illustrated in FIG. 2, first, data obtainer 41 obtains various data once information processing system 100 begins operating (step S11). Here, facility data needed for grouping that is described later and weather data for extracting energy management systems 20 do not need to be continuously obtained, as long as they can be obtained once. On the other hand, energy-supply-and-demand-amount data and energy-price data are continuously obtained over a period of time required for evaluation.

Real-world cluster generator 42 performs grouping by dividing a plurality of energy management systems 20 into one or more groups based on the facility data obtained (step S12). As described above, a process is performed in which other energy management systems 20 that are associated with facility data similar to facility data of one energy management system 20, are included in a group that includes the one energy management system 20, which is a target of evaluation. The one group that is generated includes energy management systems 20 having similar facility data.

Next, validity evaluator 43 evaluates validity of energy-saving performance and economic efficiency of energy management systems 20 in the group by comparing energy-supply-and-demand-amount data of the energy management systems 20 included in the group, which have been extracted based on weather data, and comparing costs calculated for the energy management systems 20 extracted (step S13). As an evaluation result, validity evaluator 43 assigns a score to each energy management system 20 and outputs an evaluation result indicating the scores. The evaluation result is, for example, displayed on display device 60 as an image.

### Other Embodiments

Although an embodiment has been described above, the present disclosure is not limited to the above embodiment.

For example, the information processing system described in the above-mentioned embodiment may be implemented as a single device that includes all elements, or may be implemented as a plurality of devices to which each function is assigned and where the plurality of devices cooperate with each other. In the latter case, the information processing system may be implemented as devices that correspond to information processing devices, such as a smartphone, a tablet device, a personal computer, and the like.

Furthermore, in the above-mentioned embodiment, processes to be executed by a certain processor may be performed by another processor. Furthermore, the order of the plurality of processes may be changed, and the plurality of processes may be executed in parallel with each other.

Furthermore, in the above embodiment, each element may be implemented by executing a software program suitable for each element. Each element may be implemented by a program executing component, such as a CPU or a processor, reading out and executing a software program stored in a storage medium, such as a hard disk or a semiconductor memory or the like.

Furthermore, each element may be implemented as hardware. For example, each element may be a circuit (or an integrated circuit). Such circuits may be consolidated as a single circuit, and may be configured as individual circuits. Furthermore, such circuits may each be a general-purpose circuit or a dedicated circuit.

Furthermore, general and specific aspects of the present disclosure may be implemented as a system, a device, a method, an integrated circuit, a computer program, or a recording medium, such as a computer-readable CD-ROM or the like. Furthermore, general and specific aspects of the present disclosure may be implemented as any combination of a system, a device, a method, an integrated circuit, a computer program, or a recording medium.

For example, the present disclosure may be implemented as an information processing method that is executed by a computer, and may be implemented as a program for causing a computer to execute such an information processing method. The present disclosure may be implemented as a non-transitory computer-readable recording medium having recorded thereon such a program.

Forms obtained through various modifications to the foregoing embodiment that can be conceived by those skilled in the art, as well as forms realized by combining elements and functions in the foregoing embodiment without departing from the essence of the present disclosure are included within the scope of the present disclosure.

### INDUSTRIAL APPLICABILITY

The present disclosure is effectively applicable to the operation of an energy management system.

1. An information processing method for evaluating validity of one energy management system included in a plurality of energy management systems, the information processing method being executed by a computer, the information processing method comprising:
obtaining, for each of the plurality of energy management systems, facility data of a facility managed in the energy management system;
extracting an energy management system, from among the plurality of energy management systems, that is associated with facility data that is similar to facility data associated with the one energy management system, and grouping together the energy management system extracted and the one energy management system;
obtaining, for each of the facilities managed in the energy management systems grouped together, energy-supply-and-demand-amount data; and
evaluating validity of energy-saving performance of the one energy management system by comparing the energy-supply-and-demand-amount data of each of the energy management systems grouped together, and outputting an evaluation result.

2. The information processing method according to claim 1, wherein
for each of the plurality of energy management systems, the facility data associated with the energy management system includes at least one of (i) a total-floor area of the facility, (ii) a device configuration of electrical devices provided in the facility, or (iii) a device attribute of the electrical devices provided in the facility.

3. The information processing method according to claim 1, wherein
each of the plurality of energy management systems is (i) a home energy management system (HEMS) that manages energy supply and demand on a basis of a single-household unit, (ii) a building energy management system (BEMS) that manages energy supply and demand on a basis of a business-site unit, or (iii) a factory energy management system (FEMS) that manages energy supply and demand on a basis of a factory unit.

4. The information processing method according to claim 1, wherein
each of the plurality of energy management systems is a microgrid.

5. The information processing method according to claim 1, wherein
each of the plurality of energy management systems is a community energy management system (CEMS) that manages energy supply and demand on a basis of a community unit that includes a plurality of households.

6. The information processing method according to claim 1, wherein
each of the plurality of energy management systems is a virtual power plant (VPP) that manages energy supply and demand that includes selling of electricity via a power-transmission network on a basis of a predetermined unit.

7. The information processing method according to claim 6, further comprising:
obtaining energy-price data for each of the facilities managed in the energy management systems grouped together, wherein
the energy-supply-and-demand-amount data of each of the facilities managed in the energy management systems grouped together includes an electricity-sales amount and an electricity-purchasing amount of the facility managed, and
in the outputting, validity of economic efficiency of the one energy management system is evaluated by further using (i) an electricity-sales amount and an electricity-purchasing amount of a facility managed in the one energy management system and (ii) the energy-price data obtained, and an evaluation result is output.

8. The information processing method according to claim 1, further comprising:
obtaining, for each of the plurality of energy management systems, weather data that is associated with the facility managed in the energy management system, wherein
in the outputting, the validity of the energy-saving performance of the one energy management system is evaluated by comparing, from among the energy-supply-and-demand-amount data of each of the energy management systems grouped together, energy-supply-and-demand-amount data of energy management systems having weather data similar to each other, and an evaluation result is output.

9. An information processing device that evaluates validity of one energy management system included in a plurality of energy management systems, the information processing device comprising:
a facility data obtainer that obtains, for each of the plurality of energy management systems, facility data of a facility managed in the energy management system;
a real-world cluster generator that extracts an energy management system, from among the plurality of energy management systems, that is associated with facility data that is similar to facility data associated with the one energy management system, and groups together the energy management system extracted and the one energy management system;
an energy-supply-and-demand-amount data obtainer that obtains, for each of the facilities managed in the energy management systems grouped together, energy-supply-and-demand-amount data; and
a validity evaluator that evaluates validity of energy-saving performance of the one energy management system by comparing the energy-supply-and-demand-amount data of each of the energy management systems grouped together, and outputs an evaluation result.

10. A non-transitory computer-readable recording medium having recorded thereon a program for causing the computer to execute the information processing method according to claim 1.
